(19) United States
(12) Patent Application Publication
(10) Pub. No.: US 2016/0126107 A1
(43) Pub. Date: May 5, 2016

(54) ETCHANT COMPOSITIONS FOR NITRIDE LAYERS AND METHODS OF MANUFACTURING SEMICONDUCTOR DEVICES USING THE SAME

(71) Applicant: RAM TECHNOLOGY CO., LTD., Yongin-si (KR)

(72) Inventors: Jun-Ing KIL, Gwangju-si (KR); Cheol-Won BANG, Seoul (KR); Hak-Muk KIM, Seoul (KR); Young-Su JANG, Gunpo-si (KR); Gem-Bi SHIM, Yongin-si (KR)

(21) Appl. No.: 14/691,170

(22) Filed: Apr. 20, 2015

(30) Foreign Application Priority Data
Oct. 30, 2014 (KR) 10-2014-0148922

(51) Int. Cl. H01L 21/311; C09K 13/08; H01L 27/115

(52) U.S. Cl. CPC H01L 21/31111; H01L 27/11582; C09K 13/08

(57) ABSTRACT

An etchant composition for nitride layers includes phosphoric acid in an amount ranging from about 80 weight percent to about 90 weight percent, a silicon-fluorine compound in an amount ranging from about 0.02 weight percent to about 0.1 weight percent, and a remainder of water, based on a total weight of the etchant composition. The silicon-fluorine compound includes a bond between a silicon atom and a fluorine atom (Si—F bonding).

### CROSS-REFERENCE TO RELATED APPLICATION

This application claims priority under 35 USC §119 to Korean Patent Application No. 10-2014-0148922, filed on Oct. 30, 2014 in the Korean Intellectual Property Office (KIPO), the contents of which are incorporated by reference herein in their entirety.

### BACKGROUND

1. Field

Example embodiments relate to etchant compositions for nitride layers and methods of manufacturing semiconductor devices using the same. More particularly, example embodiments relate to etchant compositions for nitride layers including an acid solution, and methods of manufacturing semiconductor devices using the same.

2. Description of the Related Art

In a fabrication of semiconductor devices, various insulative layers such as a silicon oxide layer and a silicon nitride layer may be stacked. The silicon nitride layer may be selectively etched according to a pattern structure included in the semiconductor devices.

For example, Korea Patent Publication No. 10-2005-0003163 discloses an etchant solution for a nitride layer containing a phosphoric acid and a fluoric acid. However, other insulative layers, e.g., a silicon oxide layer may be also etched by the fluoric acid, and thus a sufficient etching selectivity for the nitride layer with respect to the oxide layer may not be achieved.

Korea Patent Publication No. 10-2011-0037741 discloses a composition for etching a nitride layer which includes oxime silane. However, the composition may have a poor solubility to a solvent such as a deionized water, and thus may result in an adsorption residue on a semiconductor substrate or a silicon oxide layer.

### SUMMARY

Example embodiments provide an etchant composition for a nitride layer having an improved etching selectivity.

Example embodiments provide a method of manufacturing a semiconductor device using the etchant composition.

According to example embodiments, there is provided an etchant composition for a nitride layer. The etchant composition includes phosphoric acid in an amount ranging from about 80 weight percent to about 90 weight percent, a silicon-fluorine compound in an amount ranging from about 0.02 weight percent to about 0.1 weight percent, and a remainder of water, based on a total weight of the etchant composition. The silicon-fluorine compound includes a bond between a silicon atom and a fluorine atom (Si—F bonding).

In example embodiments, the etchant composition may include the silicon-fluorine compound in an amount ranging from about 0.03 weight percent to about 0.07 weight percent, based on the total weight of the etchant composition.

In example embodiments, the silicon-fluorine compound may include ammonium hexafluorosilicate, ammonium fluorosilicate, sodium fluorosilicate, silicon tetrafluoride or hexafluorosilicic acid. These may be used alone or in a combination thereof.

In example embodiments, a silicon compound and a fluorine compound which do not include the Si—F bonding may be excluded from the etchant composition.

In example embodiments, the silicon compound may include oxime silane, silyl sulfate and tetra ethyl ortho silicate (TEOS). The fluorine compound may include fluoric acid (HF) and ammonium fluoride.

In example embodiments, the etchant composition may further include an etching enhancer.

In example embodiments, the etching enhancer may include a sulfuric acid-based compound, or an acid ammonium-based compound except for fluoric acid ammonium.

In example embodiments, an etching selectivity for a nitride layer relative to an oxide layer of the etchant composition may exceed about 200.

In example embodiments, the etching selectivity for the nitride layer relative to the oxide layer of the etchant composition may be in a range from about 250 to about 300.

According to example embodiments, there is provided a method of manufacturing a semiconductor device. In the method, insulating interlayers and sacrificial layers are formed alternately and repeatedly on a substrate. A plurality of channels is formed through the insulating interlayers and the sacrificial layers. The insulating interlayers and the sacrificial layers are partially removed to form an opening between adjacent channels of the plurality of channels. The sacrificial layers exposed by the opening are removed using an etchant composition for nitride layers that includes phosphoric acid, a silicon-fluorine compound and a remainder of water. The silicon-fluorine compound includes a bond between a silicon atom and a fluorine atom (Si—F bonding). A gate line is formed in each of spaces from which the sacrificial layers are removed.

In example embodiments, the etchant composition may include phosphoric acid in an amount ranging from about 80 weight percent to about 90 weight percent, the silicon-fluorine compound in an amount ranging from about 0.02 weight percent to about 0.1 weight percent, and the remainder of water, based on a total weight of the etchant composition.

In example embodiments, the etchant composition may include the silicon-fluorine compound in an amount ranging from about 0.03 weight percent to about 0.07 weight percent, based on the total weight of the etchant composition.

In example embodiments, the insulating interlayer may include silicon oxide, and the sacrificial layer may include silicon nitride.

In example embodiments, an etching selectivity for the sacrificial layer relative to the insulating interlayer may be in a range from about 200 to about 300.

In example embodiments, the silicon-fluorine compound may include ammonium hexafluorosilicate, ammonium fluorosilicate, sodium fluorosilicate, silicon tetrafluoride or hexafluorosilicic acid. These may be used alone or in a combination thereof.

In example embodiments, the sacrificial layers may be removed at a temperature in a range from about 140° C. to about 170° C.

In example embodiments, a top surface of the substrate may be exposed by the opening.

In example embodiments, an impurity region may be formed at an upper portion of the substrate exposed through the opening. A filling layer pattern may be formed on the impurity region to fill the opening.

In example embodiments, a dielectric layer structure that may surround an outer sidewall of the channel may be formed.

In example embodiments, silane compound, fluoric acid and ammonium fluoride may be excluded from the etchant composition for nitride layers.

### BRIEF DESCRIPTION OF THE DRAWINGS

Example embodiments will be more clearly understood from the following detailed description taken in conjunction with the accompanying drawings. FIGS. 1 to 16 represent non-limiting, example embodiments as described herein.

FIGS. 1 to 15 are cross-sectional views and top plan views illustrating a method of manufacturing a semiconductor device in accordance with example embodiments; and

FIG. 16 is a graph showing an etching selectivity according to an amount of ammonium hexafluorosilicate.

### DESCRIPTION OF EMBODIMENTS

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this description will be thorough and complete, and will fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Etchant Compositions for Nitride Layers

The etchant composition for nitride layers (hereinafter, abbreviated as the etchant composition) according to example embodiments may include phosphoric acid, a silicon-fluorine compound and a remainder of water. In some embodiments, the etchant composition may further include an additive such as an etching enhancer.

The etchant composition may be provided on a structure including an oxide layer and a nitride layer, and the nitride layer may be etched with a high etching selectivity substantially without damaging the oxide layer by the etchant composition.

For example, the etchant composition may be used in a manufacture process of a semiconductor device for selectively etching a silicon nitride layer.

Phosphoric acid may be represented by a chemical formula of H₃PO₄, and may serve as a main ingredient for etching the nitride layer. In example embodiments, the etchant composition may include phosphoric acid in an amount ranging from about 80 weight percent to about 90 weight percent, based on a total weight of the etchant composition.

If the amount of phosphoric acid is less than about 80 weight percent, an overall etching rate may be reduced. If the amount of phosphoric acid exceeds about 90 weight percent, an etching rate for the oxide layer or a conductive layer such as a metal layer may be also increased, and thus an etching selectivity for the nitride layer may be deteriorated.

The silicon-fluorine compound may include a compound containing a Si—F bonding in a molecule, and may have an improved solubility to the composition or a phosphoric acid solution due to a fluorine atom combined to a silicon atom. Further, an etching rate of the composition may be also improved by the fluorine atom. In example embodiments, the silicon atom combined to the fluorine atom may serve as a component that may block or buffer an increase of the etching rate for the oxide layer by the fluorine atom.

Therefore, the etching rate for the nitride layer may be improved while suppressing the etching rate for the oxide layer by the inclusion of the silicon-fluorine compound. Accordingly, when a wet etching process is performed using the etchant composition, the etching selectivity for the nitride layer with respect to the oxide layer may be highly enhanced.

In example embodiments, the etchant composition may include the silicon-fluorine compound in an amount ranging from about 0.02 weight percent to about 0.1 weight percent, based on the total weight of the etchant composition. In this case, the etchant composition may have the etching selectivity for the nitride layer with respect to the oxide layer greater than about 200.

In some embodiments, the etchant composition may include the silicon-fluorine compound in an amount ranging from about 0.03 weight percent to about 0.07 weight percent, based on the total weight of the etchant composition. In this case, the etchant composition may have the etching selectivity for the nitride layer with respect to the oxide layer greater than about 250.

As described above, the etching selectivity of the etchant composition for the nitride layer may exceed about 200 or about 250 by an addition of the silicon-fluorine compound. For example, the etching selectivity of the etchant composition may range from about 200 to about 300. In an embodiment, the etching selectivity of the etchant composition may range from about 250 to about 300.

In example embodiments, the silicon-fluorine compound may include ammonium hexafluorosilicate, ammonium fluorosilicate, sodium fluorosilicate, silicon tetrafluoride or hexafluorosilicic acid. These may be used alone or in a combination thereof.

The remainder of water included in the etchant composition may include, e.g., a distilled water or a deionized water (DIW).

In some embodiments, the etchant composition may further include the additive such as the etching enhancer. The etching enhancer may include, e.g., a sulfuric acid-based compound or an acid ammonium-based compound. Silicon and fluorine components may be excluded from the sulfuric acid-based compound or the acid ammonium-based compound.

Examples of the sulfuric acid-based compound may include sulfuric acid or methanesulfonic acid. Examples of the acid ammonium-based compound may include ammonium sulfate, ammonium persulfate, ammonium acetate or ammonium phosphate. These may be used alone or in a combination thereof.

The etching enhancer may be added as a small amount so that an overall etching rate of the etchant composition may be increased, however, the etching selectivity for the nitride layer may not be reduced.

In example embodiments, the etchant composition may not include a silicon compound and/or a fluorine compound. The silicon compound and the fluorine compound may represent compounds including a silicon component and a fluorine component, respectively, while the Si—F bonding is not included therein.

Examples of the silicon compound include a silane compound such as oxime silane, silyl sulfate, tetra ethyl ortho silicate (TEOS), or the like. Examples of the fluorine compound include fluoric acid (HF), ammonium fluoride, or the like.

If the silicon compound is included in the etchant composition, at least a portion of the silicon compound may not be dissolved in the etchant composition. As a result, an etching residue including, e.g., silicon oxide may be adsorbed on a structure, e.g., a semiconductor wafer after an etching process. In this case, an additional cleaning process such as a rinse process may be further needed after the etching process.

If the fluorine compound is included in the etchant composition, etching rates for various types of layers may be simultaneously increased. Thus, the etching rate for the oxide layer may be also increased to result in a poor etching selectivity for the nitride layer.

As described above, the etchant composition for nitride layers may include the silicon-fluorine compound together with phosphoric acid. The silicon-fluorine compound may have an improved solubility while selectively increasing the etching rate for the nitride layer. Therefore, the etching selectivity for the nitride layer may be improved without generating an etching residue.

Methods of Manufacturing Semiconductor Devices

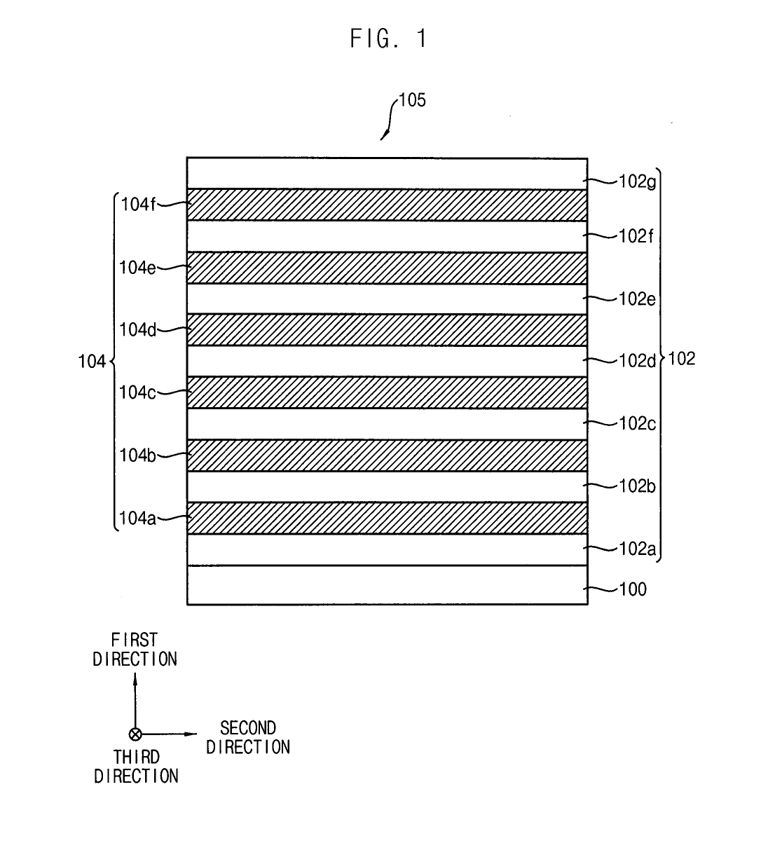

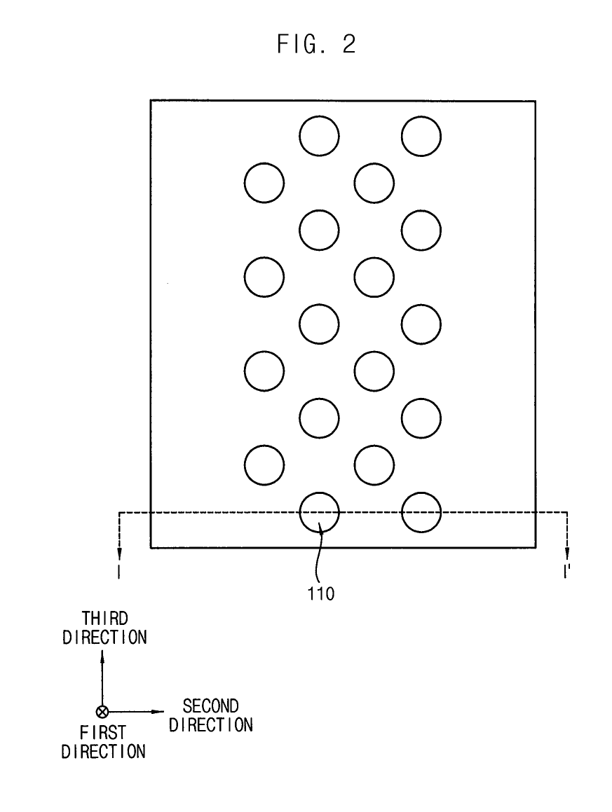

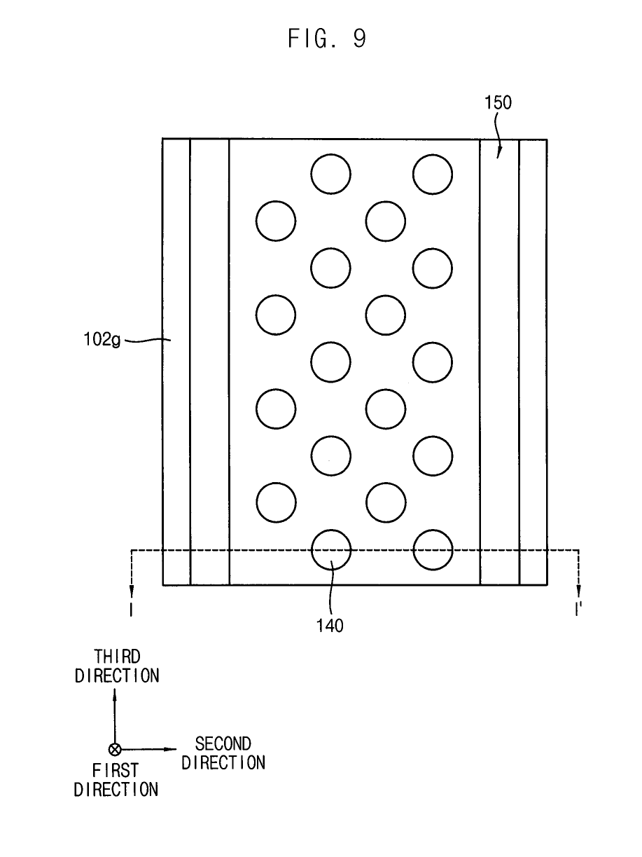

FIGS. 1 to 15 are cross-sectional views and top plan views illustrating a method of manufacturing a semiconductor device in accordance with example embodiments. Specifically, FIGS. 2 and 9 are top plan views illustrating the method of manufacturing the semiconductor device. FIGS. 1, 3 to 8, and 10 to 15 are cross-sectional views taken along lines I-I′ indicated in FIGS. 2 and 9 along a first direction.

For example, FIGS. 1 to 15 illustrate a method of manufacturing a vertical memory device including a vertical channel.

In FIGS. 1 to 15, a direction substantially vertical to a top surface of a substrate is referred to as the first direction, and two directions substantially parallel to the top surface of the substrate and crossing each other are referred to as a second direction and a third direction. For example, the second and third directions may be perpendicular to each other. Additionally, a direction indicated by an arrow in the figures and a reverse direction thereof are considered as the same direction.

Referring to FIG. 1, insulating interlayers 102 (e.g., 102a through 102g) and sacrificial layers 104 (e.g., 104a through 104f) may be formed alternately and repeatedly on a substrate 100 to form a mold structure 105.

The substrate 100 may include a semiconductor material, e.g., single crystalline silicon and/or germanium. In some embodiments, the substrate 100 may serve as a p-well of the semiconductor device.

In example embodiments, the insulating interlayers 102 may be formed using an oxide, e.g., silicon dioxide, silicon carbooxide (SiOC) and/or silicon fluorooxide (SiOF). The sacrificial layers 104 may be formed using a material that may have a high etching selectivity with respect to the insulating interlayers 102 and may be easily removed by a wet etching process. The sacrificial layers 104 may be formed using a nitride-based material, e.g., a silicon nitride and/or silicon boronitride (SiBN).

The insulating interlayer 102 and the sacrificial layer 104 may be formed by a chemical vapor deposition (CVD) process, a plasma enhanced chemical vapor deposition (PECVD) process, a spin coating process, etc. A lowermost insulating interlayer 102a may be formed by a thermal oxidation process on the top surface of the substrate 100.

The sacrificial layers 104 may be removed in a subsequent process to provide space for a ground selection line (GSL), a word line and/or a string selection line (SSL). Thus, the number of the insulating interlayers 102 and the sacrificial layers 104 may be adjusted in consideration of the number of the GSL, the word line and/or the SSL.

For example, each of the GSL and the SSL may be formed at a single level, and the word line may be formed at 4 levels. Accordingly, the sacrificial layers 104 may be formed at 6 levels, and the insulating interlayers 102 may be formed at 7 levels. In some embodiments, each of the GSL and the SSL may be formed at 2 levels, and the word line may be formed at, e.g., 4, 8 or 16 levels. In this case, the sacrificial layers 104 may be formed at 8, 12 or 20 levels, and the insulating interlayers 102 may be formed at 9, 13 or 21 levels. In an embodiment, the word line may be formed more than 16 levels, e.g., “2×n (n is an integer more than 8)” levels. However, the number of the GSL, the SSL and/or the word line may not be limited herein.

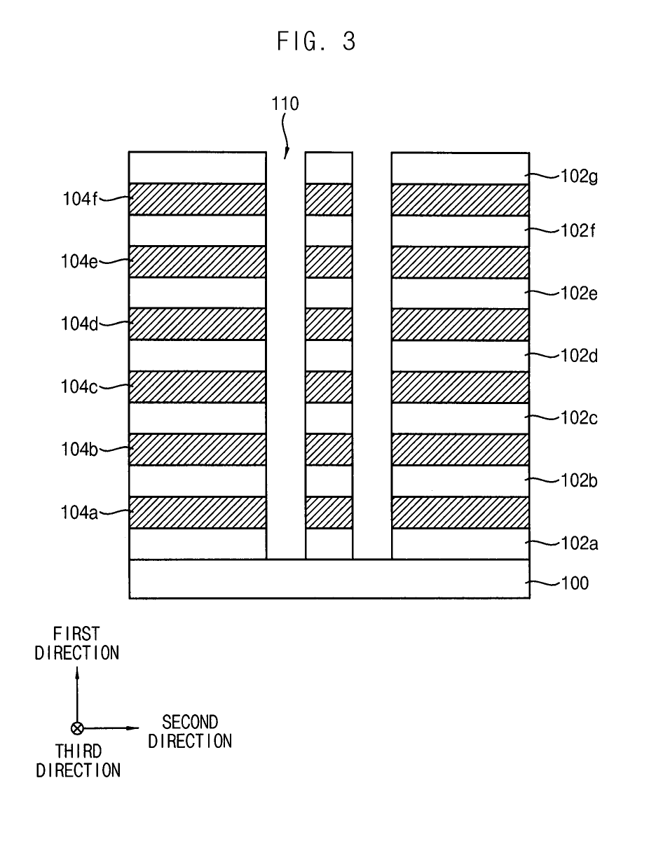

Referring to FIGS. 2 and 3, a channel hole 110 may be formed through the mold structure 105.

In some embodiments, a hard mask (not illustrated) may be formed on an uppermost insulating interlayer 102g. The insulating interlayers 102 and the sacrificial layers 104 may be partially removed using the hard mask as an etching mask to form the channel hole 110. The top surface of the substrate 100 may be exposed by the channel hole 110, and the channel hole 110 may extend in the first direction. A sidewall of the channel hole 110 may be substantially vertical with respect to the top surface of the substrate 100. However, the sidewall of the channel hole 110 may be tapered with respect to the top surface of the substrate 100 due to characteristics of a dry etching process.

The hard mask may be formed using a material having an etching selectivity with respect to the insulating interlayers 102 and the sacrificial layers 104. For example, the hard mask may be formed using a photoresist material, or silicon-based or carbon based spin-on hard mask (SOH) materials. The hard mask may be removed by, e.g., an ashing process and/or a strip process after the formation of the channel holes 110.

As illustrated in FIG. 2, a plurality of channel holes 110 may be formed along the third direction to form a channel hole column. A plurality of the channel hole columns may be arranged along the second direction.

The channel hole columns may be arranged such that the channel holes 110 included therein may form a zigzag arrangement. Thus, a density of the channel holes 110 may be improved in a unit area of the substrate 100.

The predetermined number of the channel hole columns may define a channel hole group. For example, 4 channel hole columns illustrated in FIG. 2 may define one channel hole group. A plurality of the channel hole groups may be formed along the second direction.

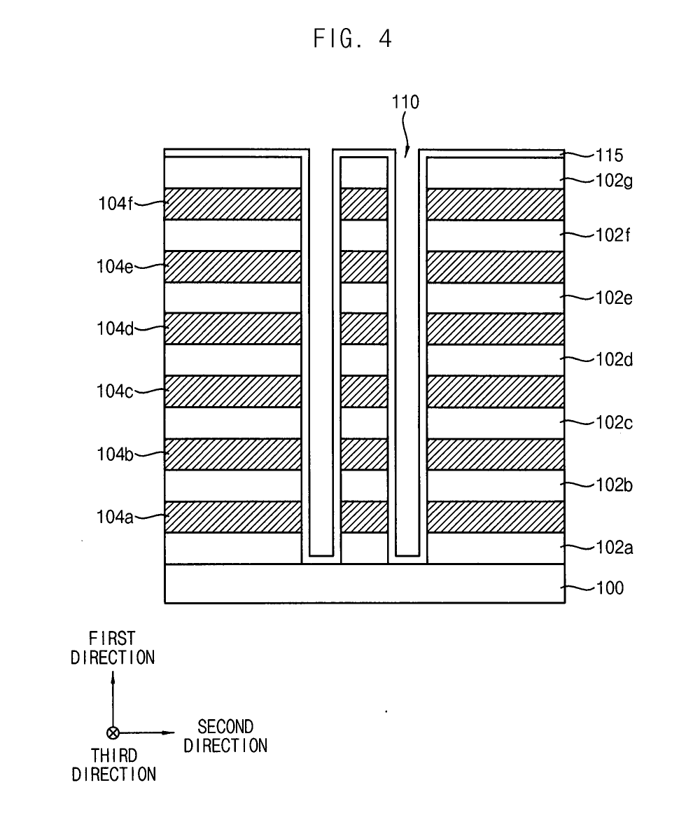

Referring to FIG. 4, a dielectric layer 115 may be formed on sidewalls and bottoms of the channel holes 110 and on a top surface of the uppermost insulating interlayer 102g.

In some embodiments, the dielectric layer 115 may have a multi-stacked structure including a blocking layer, a charge storage layer and a tunnel insulation layer.

The blocking layer may be formed using an oxide, e.g., silicon oxide, the charge storage layer may be formed using silicon nitride or a metal oxide, and the tunnel insulation layer may be formed using an oxide, e.g., silicon oxide. In some embodiments, the dielectric layer 115 may have an oxide-nitride-oxide (ONO) layer structure. The first blocking layer, the charge storage layer and the tunnel insulation layer may be formed by a CVD process, a PECVD process, an atomic layer deposition (ALD) process, etc.

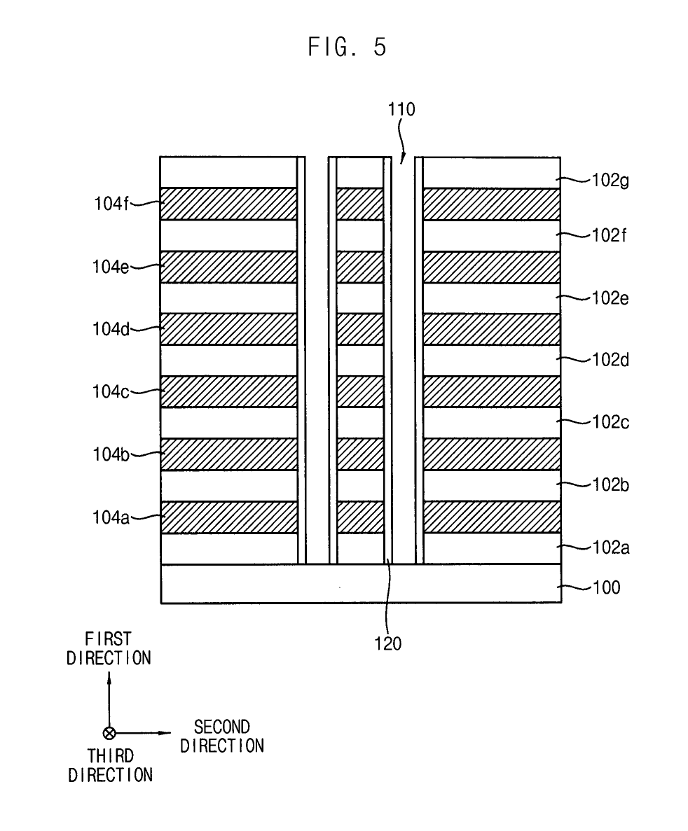

Referring to FIG. 5, the dielectric layer 115 may be partially removed to form a dielectric layer structure 120.

For example, upper and lower portions of the dielectric layer 115 may be removed by an etch-back process. Accordingly, portions of the dielectric layer 115 formed on the top surface of the uppermost insulating interlayer 102g and the top surface of the substrate 100 may be substantially removed to form the dielectric layer structure 120.

The dielectric layer structure 120 may be formed in each of the channel holes 110. For example, the dielectric layer structure 120 may be formed on the sidewall of the channel hole 110, and may have a substantially straw shape. The top surface of the substrate 100 may be exposed again after the formation of the dielectric layer structure 120.

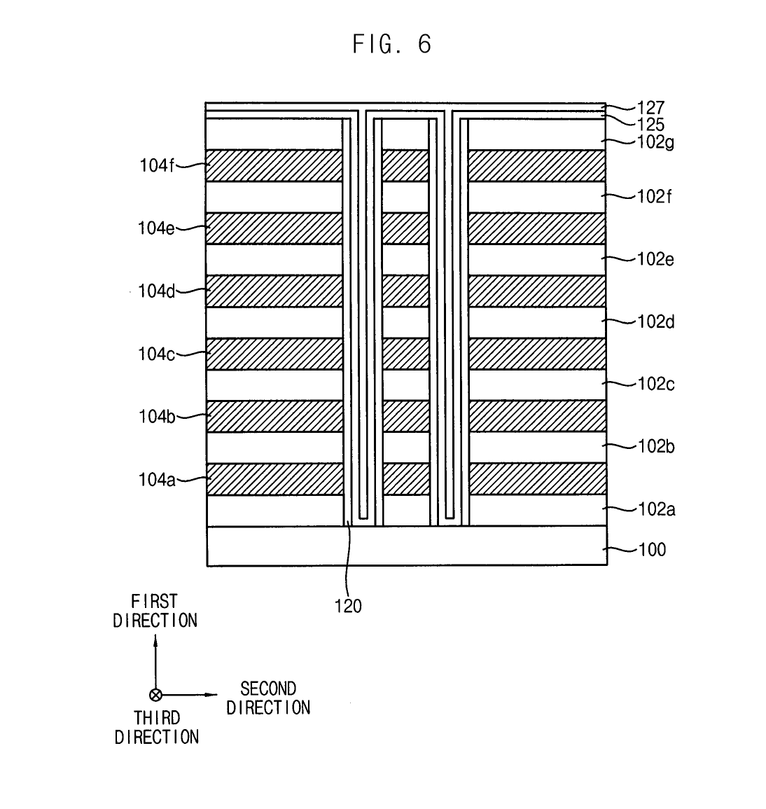

Referring to FIG. 6, a channel layer 125 may be formed on surfaces of the uppermost insulating interlayer 102g and the dielectric layer structure 120, and the top surface of the substrate 100, and then a first filling layer 127 may be formed on the channel layer 125 to fill a remaining portion of the channel hole 110.

In example embodiments, the channel layer 125 may be formed polysilicon or amorphous silicon which may be optionally doped with impurities. In some embodiments, a heat treatment or a laser beam irradiation may be further performed on the channel layer 125. In this case, the channel layer 125 may include single crystalline silicon and defects in the channel layer 125 may be cured.

The first filling layer 127 may be formed using an insulation material, e.g., silicon oxide or silicon nitride. The channel layer 125 and the first filling layer 127 may be formed by a CVD process, a PECVD process, an ALD process, etc.

In some embodiments, the channel layer 125 may be formed to fully fill the channel hole 110. In this case, the formation of the first filling layer 127 may be omitted.

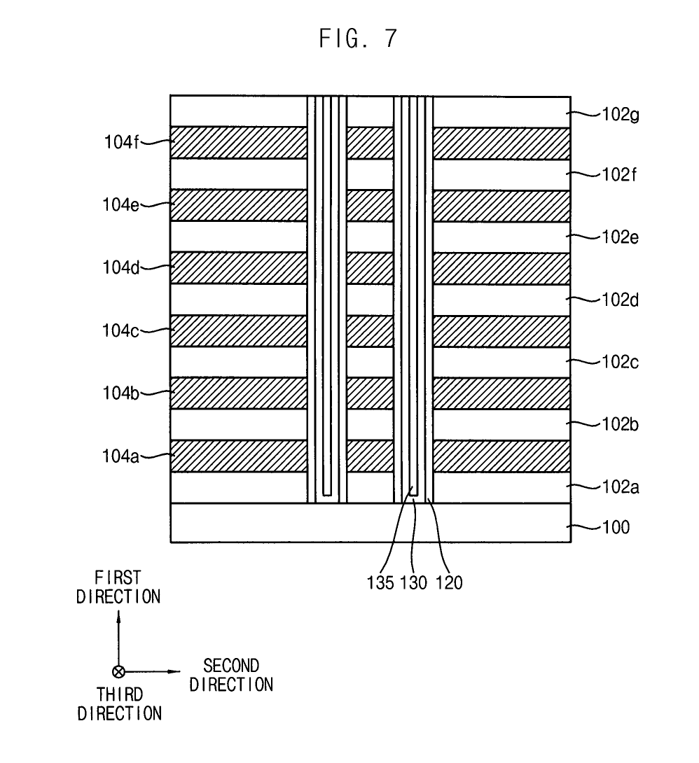

Referring to FIG. 7, the first filling layer 127 and the channel layer 125 may be planarized until the uppermost insulating interlayer 102g is exposed to form a channel 130 and a first filling layer pattern 135 sequentially stacked from a sidewall of the dielectric layer structure 120 and filling the channel hole 110. The planarization process may include an etch-back process and/or a chemical mechanical polish (CMP) process

The channel 130 may have a substantially cup shape, and may be in contact with the exposed top surface of the substrate 100. The first filling layer pattern 135 may have a substantially solid cylindrical shape or a substantially pillar shape. In some embodiments, if the channel layer 125 fully fills the channel hole 110, the first filling layer pattern 135 may be omitted and the channel 130 may have a substantially solid cylindrical shape or a substantially pillar shape.

After the formation of the channel 130 in each of the channel holes 110, a channel column may be defined according to the above-mentioned channel hole column. For example, 4 channel columns may define one channel group.

In some embodiments, a semiconductor pattern (not illustrated) filling a lower portion of the channel hole 110 may be further formed before the formation of the dielectric layer structure 120 and the channel 130. For example, the semiconductor pattern may be formed by a selective epitaxial growth (SEG) process using the top surface of the substrate 100 as a seed. The semiconductor pattern may include polysilicon or single crystalline silicon.

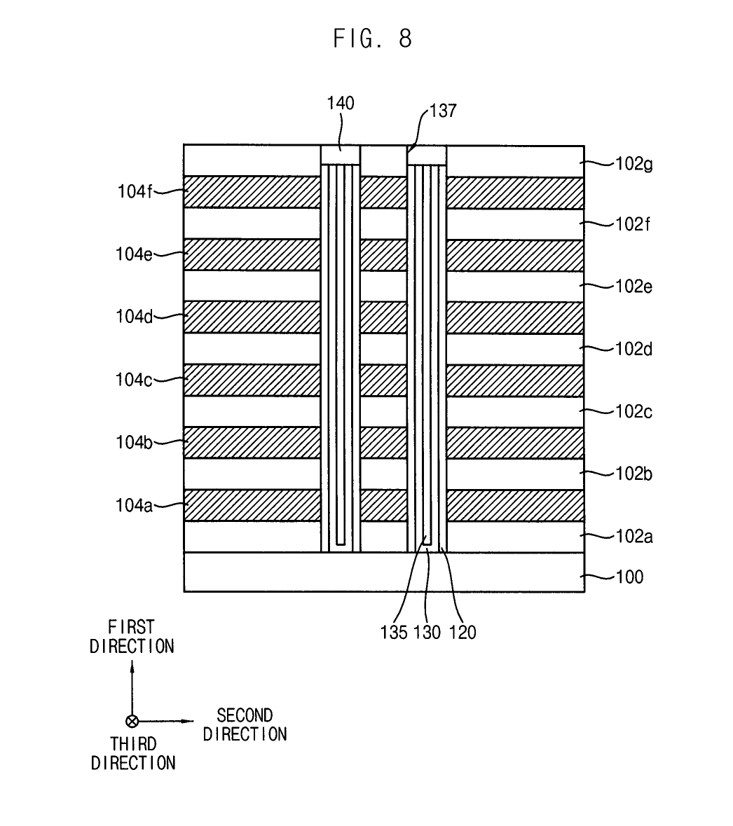

Referring to FIG. 8, a pad 140 capping an upper portion of the channel hole 110 may be formed.

For example, upper portions of the dielectric layer structure 120, the channel 130 and the first filling layer pattern 135 may be removed by an etch-back process to form a recess 137. A pad layer filling the recess 137 may be formed on the dielectric layer structure 120, the channel 130, the first filling layer pattern 135 and the uppermost insulating interlayer 102g. An upper portion of the pad layer may be planarized until a top surface of the uppermost insulating interlayer 102g is exposed to obtain the pad 140. In some embodiments, the pad layer may be formed using polysilicon optionally doped with n-type impurities by, e.g., a CVD process. In some embodiments, a preliminary pad layer may be formed using amorphous silicon, and then a crystallization process may be performed thereon to form the pad layer. The planarization process may include a CMP process.

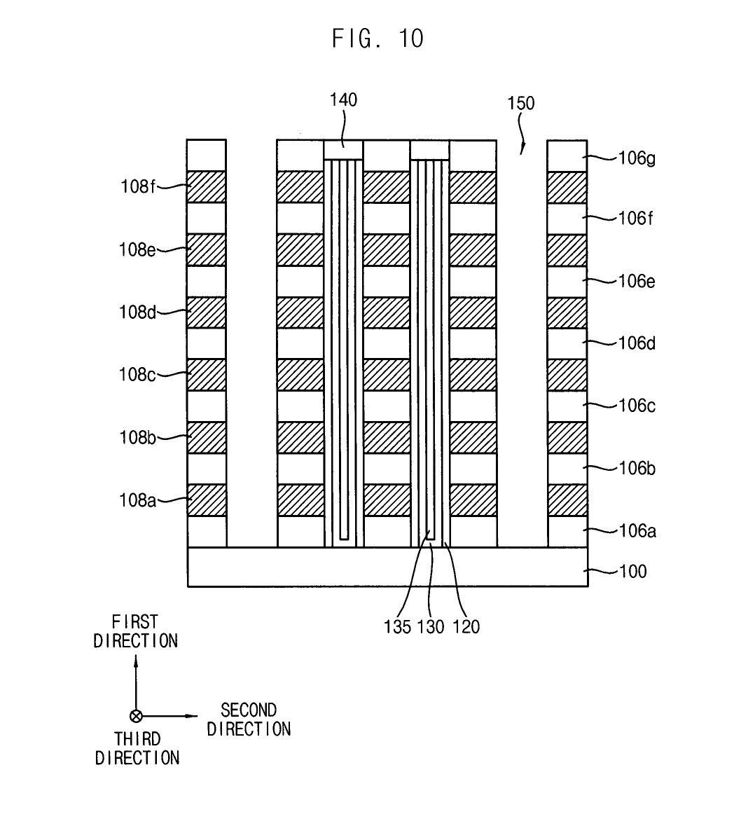

Referring to FIGS. 9 and 10, the mold structure 105 may be partially etched to form openings 150.

For example, a mask pattern (not illustrated) covering the pads 140 and exposing portions of the uppermost insulating interlayer 102g between some of the channel columns may be formed. A dry etching process may be performed using the mask pattern as an etching mask, such that portions of the insulating interlayers 302 and the sacrificial layers 304 between the some of the channel columns may be removed to form the openings 150. The hard mask may be formed using a photoresist material or an SOH material. The hard mask may be removed by an ashing process and/or a strip process after the formation of the openings 150.

The opening 150 may extend through the mold structure 105, and the top surface of the substrate 100 may be exposed therethrough. The opening 150 may extend in the third direction, and a plurality of the openings 150 may be formed along the second direction.

The opening 150 may serve as a gate line cut region. The channel group may be defined between the openings 150 neighboring each other in the second direction. In some embodiments, the four channel columns may form the channel group between the openings 150.

The insulating interlayers 102 and the sacrificial layers 104 may be changed into insulating interlayer patterns 106 (e.g., 106a through 106g) and sacrificial layer patterns 108 (e.g., 108a through 1080, respectively, by the formation of the openings 150. The insulating interlayer patterns 106 and the sacrificial layer patterns 108 may have a linear shape surrounding the channel group.

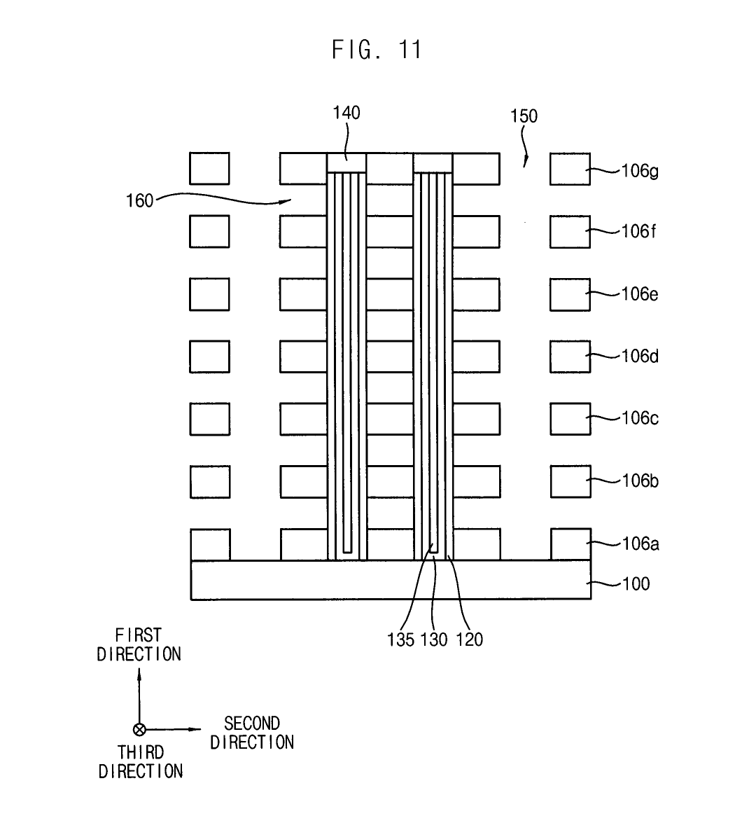

Referring to FIG. 11, the sacrificial layer patterns 108, sidewalls of which are exposed by the opening 350 may be removed. By the removal of the sacrificial layer patterns 108, gaps 160 may be defined between the insulating interlayer patterns 106 adjacent in the first direction. An outer sidewall of the dielectric layer structure 135 may be partially exposed by the gap 360.

As described above, the sacrificial layer pattern 108 and the insulating interlayer pattern 106 may include the nitride-based material and the oxide-based material, respectively. In example embodiments, the sacrificial layer pattern 108 and the insulating interlayer pattern 106 may include silicon nitride (Si₃N₄) and silicon oxide (SiO₂), respectively.

Accordingly, the sacrificial layer patterns 108 may be selectively removed using an etchant composition for nitride layers in accordance with example embodiments.

The etchant composition according to example embodiments may include phosphoric acid, a silicon-fluorine compound and a remainder of water. In some embodiments, the etchant composition may include phosphoric acid in an amount of about 80 weight percent to about 90 weight percent, the silicon-fluorine compound in an amount of about 0.02 weight percent to about 0.1 weight percent, and the remainder of water, based on a total weight of the etchant composition.

In an embodiment, the etchant composition may include phosphoric acid in an amount of about 80 weight percent to about 85 weight percent, the silicon-fluorine compound in an amount of about 0.03 weight percent to about 0.07 weight percent, and the remainder of water, based on the total weight of the etchant composition.

In some embodiments, the etchant composition may further include the above-mentioned etching enhancer.

In example embodiments, the sacrificial layer patterns 108 may be removed by the etchant composition with an etching selectivity of at least 200 relative to the insulating interlayer patterns 106. In an embodiment, the sacrificial layer patterns 108 may be removed by the etchant composition with an etching selectivity of at least 250 relative to the insulating interlayer patterns 106. For example, the etching selectivity for the sacrificial layer pattern 108 relative to the insulating interlayer pattern 106 may range from about 200 to about 300.

When the insulating interlayer patterns 106 and the sacrificial layer patterns 108 are repeatedly and alternately stacked or 3-dimensionally stacked, the insulating interlayer patterns 106 may be damaged during the removal of the sacrificial layer patterns 108 even though an etchant composition is designed to have a predetermined etching selectivity. Thus, in a subsequent process for forming a gate line in each gap 160, the gate lines may not be completely separated between the neighboring levels to result in an operational failure.

Further, if the insulating interlayer pattern 106 is also etched during the removal of the sacrificial layer pattern 108, an etching residue including, e.g., silicon oxide may be adsorbed on the substrate 100 or other structures.

Therefore, in a manufacture process for a highly integrated vertical memory device, the etchant composition for nitride layers having the etching selectivity greater than about 200 may be needed.

In a comparative example, fluoric acid or a fluorine compound such as ammonium fluoride may be contained in an etchant composition so as to increase the etching selectivity for nitride layers. However, the etching selectivity greater than about 200 may not be obtained only by the inclusion of the fluorine compound.

In a comparative example, a silicon compound or a silane compound such as silyl sulfate or oxime silane may be contained in an etchant composition so as to increase the etching selectivity for nitride layers. However, the silicon compound may have a poor solubility to water or phosphoric acid to further generate silicon oxide during an etching process, which may be adsorbed on the substrate 100 or other structures.

However, according to example embodiments, the etchant composition for nitride layers may include the silicon-fluorine compound which may be easily dissolved in water or phosphoric acid. Thus, an adsorption of silicon oxide may not be caused, and the etching selectivity for the nitride layer greater than about 200 may be realized. Therefore, the sacrificial layer patterns 108 may be selectively removed without damaging the insulating interlayer patterns 106 and without generating etching residues.

As described above, the silicon-fluorine compound may include ammonium hexafluorosilicate, ammonium fluorosilicate, sodium fluorosilicate, silicon tetrafluoride, hexafluorosilicic acid or a combination thereof.

In example embodiments, the etching process for the sacrificial layer patterns 108 may be performed at a temperature ranging from about 140° C. to about 170° C. In some embodiments, the etching process may be performed at a temperature of about 160° C.

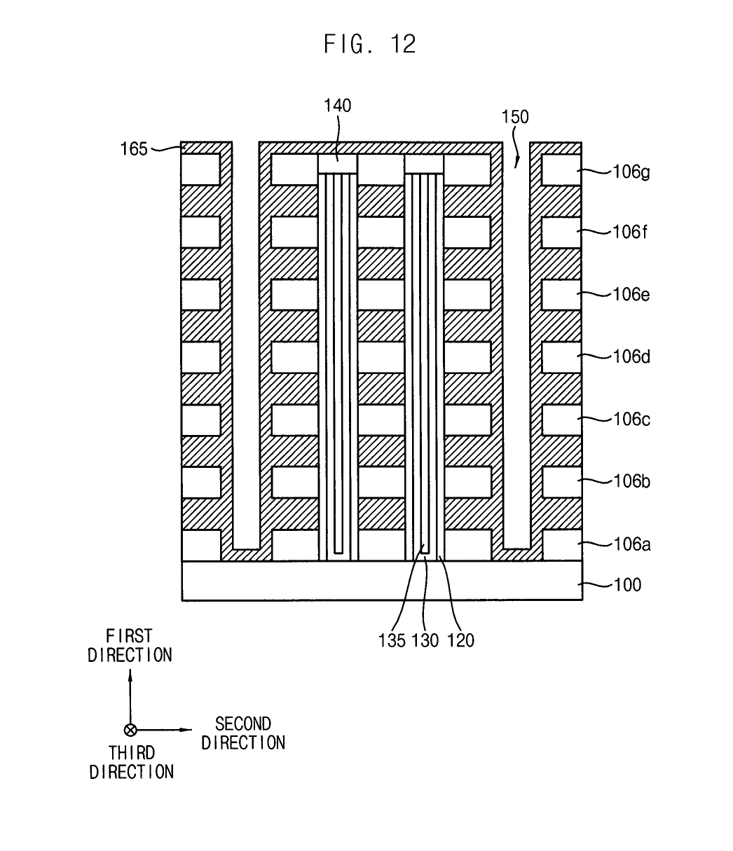

Referring to FIG. 12, a gate electrode layer 165 filling the gaps 160 may be formed.

In example embodiments, the gate electrode layer 165 may be formed along the exposed outer sidewalls of the dielectric layer structure 120, surfaces of the insulating interlayer patterns 106, the exposed top surface of the substrate 100, and top surfaces of the pads 140. The gate electrode layer 165 may fully fill the gaps 160, and may partially fill the opening 150.

The gate electrode layer 165 may be formed using a metal or a metal nitride having low resistance and work function, e.g., tungsten, tungsten nitride, titanium, titanium nitride, tantalum, tantalum nitride, platinum, etc. In some embodiments, the gate electrode layer 165 may have a multi-layered structure including a barrier layer and a metal layer. The barrier layer may be formed of the metal nitride. The gate electrode layer 165 may be formed by a CVD process, a PECVD process, an ALD process, a physical vapor deposition (PVD) process or sputtering process.

In some embodiments, an additional blocking layer including, e.g., silicon oxide or a metal oxide may be further formed on innerwalls of the gaps 160 and the surfaces of the insulating interlayer patterns 106 before the formation of the gate electrode layer 165.

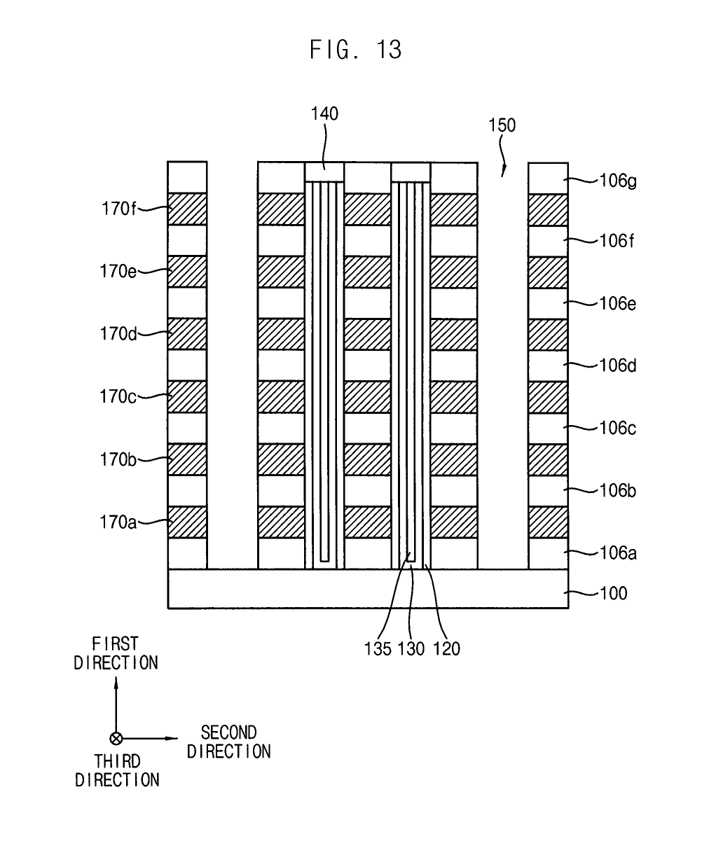

Referring to FIG. 13, the gate electrode layer 165 may be partially removed to form gate lines 170 (e.g., 170a through 170f) in the gaps 160.

For example, an upper portion of the gate electrode layer 165 may be planarized by, e.g., a CMP process until the top surface of an uppermost insulating interlayer pattern 106g is exposed. Portions of the gate electrode layer 165 formed in the opening 150 and the top surface of the substrate 100 may be etched to form the gate lines 170 in each gap 160. The gate electrode layer 165 may be partially etched through a wet etching process using, e.g., hydrogen peroxide (H₂O₂).

The gate lines 170 may include the GSL, the word line and/or the SSL sequentially stacked and spaced apart from each other in the first direction. For example, a lowermost gate line 170a may serve as the GSL. Four gate lines 170b, 170c, 170d and 170e on the GSL may serve as the word lines. An uppermost gate line 170f on the word line may serve as the SSL. However, the stacked number of the GSL, the word line and the SSL may be properly adjusted in consideration of a circuit design and a degree of integration of the vertical memory device.

The gate line 170 at each level may extend in the third direction and may surround the dielectric layer structures 120 and the channels 130. The gate line 170 at each level may surround the predetermined number of the channel columns. For example, the gate line 170 at each level may surround the channel group including, e.g., the 4 channel columns. Thus, a gate line structure may be defined by the gate lines 170 stacked in the first direction, each of which may extend in the third direction to surround the channel group.

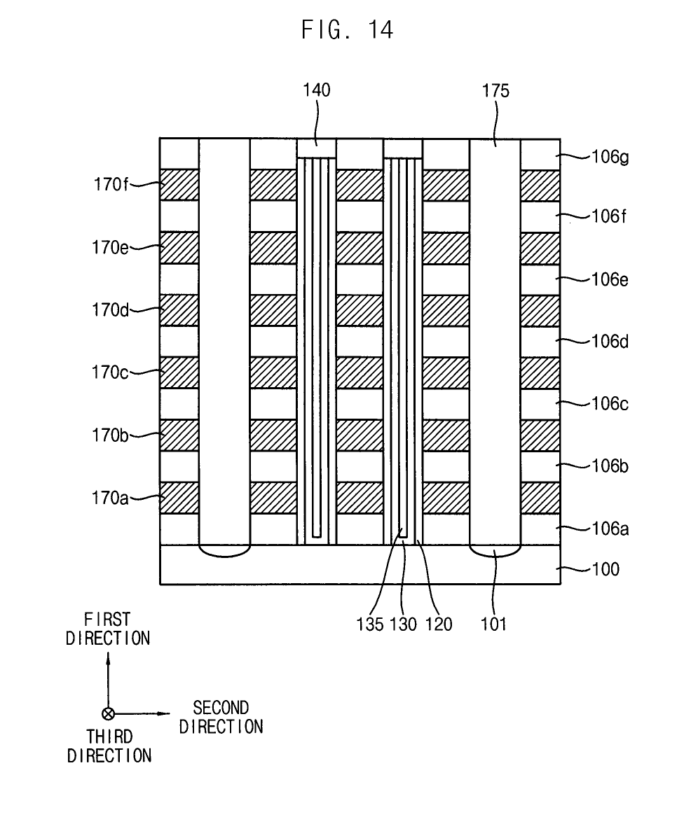

Referring to FIG. 14, an impurity region 101 may be formed at upper portion of the substrate 100 exposed through the opening 150, and a second filling layer pattern 175 may be formed in the opening 150.

For example, an ion implantation mask (not illustrated) covering the pads 140 may be formed on the uppermost insulating interlayer pattern 106g. N-type impurities such as phosphorous (P) and/or arsenic (As) may be implanted through the opening 150 to form the impurity region 101.

The impurity region 101 may extend in the third direction and may serve as a common source line (CSL) of the vertical memory device. In some embodiments, a metal silicide pattern, e.g., a cobalt silicide pattern or a nickel silicide pattern may be further formed on the impurity region 101.

A second filling layer may be formed on the substrate 100, the uppermost insulating interlayer pattern 106g and the pad 140 to fill the openings 150. An upper portion of the second filling layer may be planarized by, e.g., a CMP process or an etch-back process until the uppermost insulating interlayer pattern 106g is exposed to form the second filling layer pattern 175. The second filling layer may be formed using an insulation material, e.g., silicon oxide by, e.g., a CVD process.

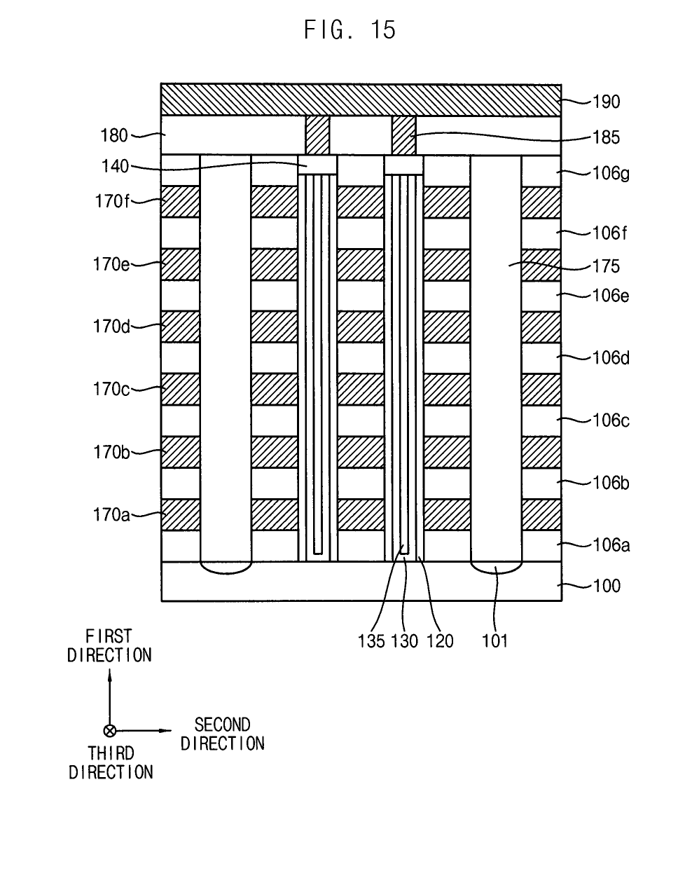

Referring to FIG. 15, an upper insulation layer 180 may be formed on the uppermost insulating interlayer pattern 106g, the second filling layer pattern 175 and the pad 140. The upper insulation layer 180 may be formed using an insulation material, e.g., silicon oxide by, e.g., a CVD process or a spin coating process.

In some embodiments, the second filling layer may be formed to fill the openings 150 and cover the uppermost insulating interlayer pattern 106g and the pad 140. In this case, the formation of the upper insulation layer 180 may be omitted.

A bit line contact 185 may be formed through the upper insulation layer 180 to contact the pad 140. A bit line 190 may be formed on the upper insulation layer 180 to be electrically connected to the bit line contact 185. The bit line contact 185 and the bit line 190 may be formed using a metal, a metal nitride or doped polysilicon by a PVD process, an ALD process or a sputtering process.

A plurality of the bit line contacts 185 may be formed according to an arrangement of the pads 140 to form a bit line contact array. The bit line 190 may be electrically connected to a plurality of the pads 140 via the bit line contacts 185. The bit line 190 may extend in the second direction, and a plurality of the bit lines 190 may be arranged along the third direction.

Hereinafter, etching properties of the etchant composition for nitride layers according to example embodiments will be described in more detail with reference to Experimental Examples.

### Experimental Example 1

### Evaluations on Etching Properties of Etchant Compositions

Oxime silane or TEOS as a silicon compound, and NH₄HF₂ or NH₄F as a fluorine compound were added to 85% phosphoric acid and water (DIW) to prepare etchant compositions of Comparative Examples. Ammonium hexafluorosilicate (AHFS) as a silicon-fluorine compound was added to 85% phosphoric acid and water to prepare etchant compositions of Examples.

Each of the etchant compositions was stirred by a centrifugation at a rate of about 4,000 rpm, and monitored to decide whether ingredients of the compositions were fully dissolved in phosphoric acid.

Etching rates for a silicon nitride layer (Si₃N₄) and a thermal oxide layer (SiO₂) were measured at 160° C. using the etchant compositions, and etching selectivities were calculated using the measured results.

The ingredients of the etchant compositions of Comparative Examples and Examples, and the experimental results are listed in Tables 1 and 2 below.

TABLE 1
Ingredients of the Etchant Compositions

| | Amount (wt %) | | | | | | |
|---|---|---|---|---|---|---|---|
| | | Silicon | | | | | |
| | Phosphoric | Compound | | | Fluorine | | |
| | Acid | Oxime | | | Compound | | |
| | (H₃PO₄) | Silane | TEOS | AHFS | NH₄HF₂ | NH₄F | DIW |
| Ref | 85.00 | — | — | — | — | — | 15.00 |
| Comparative | 84.95 | 0.1 | — | — | — | — | 14.95 |
| Example 1 | | | | | | | |
| Comparative | 84.95 | — | 0.1 | — | — | — | 14.95 |
| Example 2 | | | | | | | |
| Comparative | 83.30 | 0.1 | — | — | — | 0.5 | 16.10 |
| Example 3 | | | | | | | |
| Comparative | 83.30 | 0.1 | — | — | 0.5 | — | 16.10 |
| Example 4 | | | | | | | |
| Example 1 | 84.98 | — | — | 0.05 | — | — | 14.98 |
| Example 2 | 84.95 | — | — | 0.1 | — | — | 14.95 |
| Example 3 | 84.75 | — | — | 0.5 | — | — | 14.75 |

TABLE 2
Evaluation Results of the Etchant Compositions

| | | Etching Rate (Å/min) | | |
|---|---|---|---|---|
| | Dissolution after | Nitride | Oxide | Etching |
| | Centrifugation | Layer | Layer | Selectivity |
| Ref | — | 52.93 | 0.95 | 55.72 |
| Comparative | Not dissolved | — | — | — |
| Example 1 | | | | |
| Comparative | Not dissolved | — | — | — |
| Example 2 | | | | |
| Comparative | Dissolved | 109.99 | 195.68 | 0.56 |
| Example 3 | | | | |
| Comparative | Dissolved | 109.04 | 76.08 | 1.43 |
| Example 4 | | | | |
| Example 1 | Dissolved | 134.89 | 0.47 | 285.78 |
| Example 2 | Dissolved | 148.19 | 0.71 | 208.42 |
| Example 3 | Dissolved | 245.56 | 14.90 | 16.48 |

Referring to Tables 1 and 2, in the etchant compositions of Comparative Examples 1 and 2 including the silicon compound, the silicon compound was not substantially dissolved in the composition. As a result, the etching rate could not be measured.

In the etchant compositions of Comparative Examples 3 and 4 additionally including the fluorine compound, the ingredients of the composition were dissolved by the addition of the fluorine compound. However, the etching selectivities for the nitride layer were below 2. Thus, it may be acknowledged that the overall etching rates were increased by the fluorine compound, however, the etchant composition cannot be used as a selective composition for the nitride layer because of the poor etching selectivity thereof.

In the etchant compositions of Examples 1 to 3 including AHFS as the silicon-fluorine compound, the etching selectivities much greater than those of Comparative Examples were obtained. In Examples 1 and 2, the etching selectivities greater than 200 were obtained. Specifically, in Example 1 in which the amount of AHFS was 0.05 wt %, the etching selectivity above 285 was obtained,

### Experimental Example 2

### Measurements of Etching Selectivities According to an Amount of the Silicon-Fluorine Compound

Etching rates (Å/min) and etching selectivities of etchant compositions including a silicon-fluorine compound and phosphoric acid (85 wt %) were measured changing a type and a concentration of the a silicon-fluorine compound in substantially the same manner as that of Experimental Example 1. The results are listed in Table 3 below.

TABLE 3

| | | Amount (wt %) | | | | |
|---|---|---|---|---|---|---|
| | | 0 | 0.01 | 0.05 | 0.1 | 0.5 |
| AHFS | Etching Rate | 52.93 | 102.4 | 134.89 | 148.18 | 245.56 |
| | (for nitride | | | | | |
| | layer) | | | | | |
| | Etching Rate | 0.95 | 0.81 | 0.47 | 0.71 | 14.9 |
| | (for oxide layer) | | | | | |
| | Etching | 56 | 126 | 287 | 209 | 16 |
| | Selectivity | | | | | |
| AFS | Etching Rate | 52.93 | 59.4 | 68.4 | 94.5 | 105.7 |
| | (for nitride | | | | | |
| | layer) | | | | | |
| | Etching Rate | 0.95 | 0.5 | 0.28 | 0.47 | 5.4 |
| | (for oxide layer) | | | | | |
| | Etching | 56 | 119 | 244 | 201 | 20 |
| | Selectivity | | | | | |
| SFS | Etching Rate | 52.93 | 57.9 | 64.5 | 87.6 | 98.4 |
| | (for nitride | | | | | |
| | layer) | | | | | |
| | Etching Rate | 0.95 | 0.58 | 0.29 | 0.38 | 2.4 |
| | (for oxide layer) | | | | | |
| | Etching | 56 | 100 | 222 | 231 | 41 |
| | Selectivity | | | | | |
| STF | Etching Rate | 52.93 | 82.6 | 124.1 | 139.2 | 210.4 |
| | (for nitride | | | | | |
| | layer) | | | | | |
| | Etching Rate | 0.95 | 0.81 | 0.51 | 0.68 | 15.9 |
| | (for oxide layer) | | | | | |
| | Etching | 56 | 102 | 243 | 205 | 13 |
| | Selectivity | | | | | |
| HFSA | Etching Rate | 52.93 | 105.4 | 130.47 | 145.7 | 239.5 |
| | (for nitride | | | | | |
| | layer) | | | | | |
| | Etching Rate | 0.95 | 0.78 | 0.5 | 0.75 | 13.8 |
| | (for oxide layer) | | | | | |
| | Etching | 56 | 135 | 261 | 194 | 17 |
| | Selectivity | | | | | |

* AFS: ammonium fluorosilicate, SFS: sodium fluorosilicate, STF: silicon tetrafluoride, HFSA: hexafluorosilicic acid

Referring to Table 3, as the amount of the silicon-fluorine compound exceeded about 0.01 wt %, the etching selectivities above about 100 were obtained commonly in the 5 cases. Further, as the amount of the silicon-fluorine compound reached about 0.05 wt %, the etching selectivities above about 200 were obtained. Specifically, when the AHFS and HFSA were used, the etching selectivities exceeded 250.

An etching selectivity was measured at 160° C., changing the amount of AHFS in a more segmented unit.

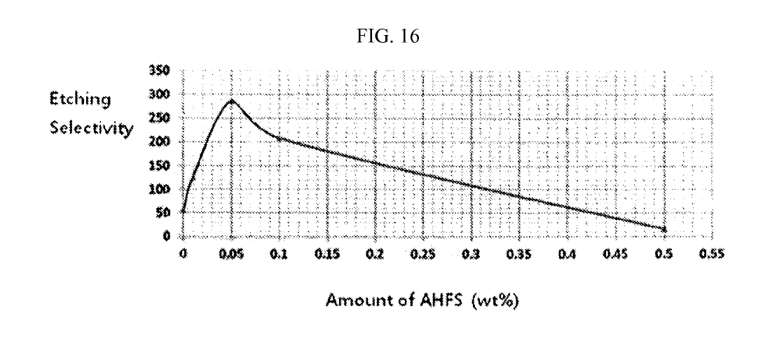

FIG. 16 is a graph showing an etching selectivity according to an amount of ammonium hexafluorosilicate. In FIG. 16, X-axis represents the amount of AHFS, and Y-axis represents the etching selectivity (silicon nitride/silicon oxide).

Referring to FIG. 16, when the amount of AHFS was between about 0.02 wt % and about 0.1 wt %, the etching selectivity above about 200 was obtained. Further, the etching selectivity was above 250 at the amount of AHFS between about 0.03 wt % to about 0.07 wt %. A maximum etching selectivity was achieved at the amount of AHFS of about 0.05 wt %.

As shown in FIG. 16, as the amount of AHFS exceeded about 0.1 wt %, the etching selectivity was reduced substantially linearly. Thus, it may be acknowledged that an etching rate for an oxide layer was increased as an amount of fluorine in the composition became excessively increased.

### Experimental Example 3

### Measurements of Etching Selectivities According to a Temperature

Etching rates (Å/min) for a nitride layer and an oxide layer were measured using an etchant composition that included phosphoric acid (85 wt %), a silicon-fluorine compound (0.05 wt %) and a remainder of water while changing a temperature. The results are listed in Tables 4 to 6 below.

TABLE 4
Etching rates for the nitride layer (Si₃N₄)

| Temp (° C.) | AHFS | AFS | SFS | STF | HFS |
|---|---|---|---|---|---|
| 130 | 28.26 | 12.42 | 11.71 | 22.53 | 23.69 |
| 135 | 39.86 | 17.52 | 16.52 | 31.78 | 33.41 |
| 140 | 56.87 | 24.71 | 23.30 | 44.83 | 47.13 |
| 145 | 69.52 | 35.25 | 33.24 | 63.96 | 67.24 |
| 150 | 102.09 | 51.77 | 48.82 | 93.92 | 98.74 |
| 160 | 134.89 | 68.4 | 64.5 | 124.1 | 130.47 |

TABLE 5
Etching rates for the oxide layer (SiO₂)

| Temp (° C.) | AHFS | AFS | SFS | STF | HFS |
|---|---|---|---|---|---|
| 130 | 0 | 0 | 0 | 0 | 0 |
| 135 | 0 | 0 | 0 | 0 | 0 |
| 140 | 0 | 0 | 0 | 0 | 0 |
| 145 | 0 | 0 | 0 | 0 | 0 |
| 150 | 0.046 | 0.028 | 0.022 | 0.038 | 0.037 |
| 160 | 0.47 | 0.28 | 0.29 | 0.51 | 0.5 |

TABLE 6
Etching selectivities for the nitride layer relative to the oxide layer

| Temp (° C.) | AHFS | AFS | SFS | STF | HFS |
|---|---|---|---|---|---|
| 130 | — | — | — | — | — |
| 135 | — | — | — | — | — |
| 140 | — | — | — | — | — |
| 145 | — | — | — | — | — |
| 150 | 2219.35 | 1848.85 | 2218.91 | 2471.68 | 2668.78 |
| 160 | 287 | 244 | 222 | 243 | 261 |

Referring to Tables 4 to 6, the oxide layer was not substantially etched at a temperature less than about 140° C., and thus the etching selectivity was calculated as indefinite (indicated as “-” in Table 6). However, in the temperature range, the etching rate for the nitride layer was limited below about 50 Å/min, and thus a process time for etching the nitride layer may be excessively increased in a real manufacture process.

At a temperature of about 140° C., the etching rate for the nitride layer was greater than 50 Å/min which is a critical rate in the real manufacture process, when using AHFS. When STF and HFS were used, the etching rate for the nitride layer near the critical rate was obtained. The oxide layer was not substantially etched so that the etching selectivity was increased to an indefinite value.

At a temperature of about 150° C., the etching rate for the nitride layer was greater than 100 Å/min when using AHFS. The etching rate for the nitride layer when using STF and HFS was also near 100 Å/min. The etching selectivities were generally greater than about 2000.

At a temperature of about 160° C., the sufficient etching selectivities greater than about 200 were obtained in all silicon-fluorine compounds, and the etching rates for the nitride layer were generally greater than about 100 Å/min.

It may be predicted that the etching selectivity may become less than about 200 at a temperature greater than about 170° C. because of an increase of the etching rate for the oxide layer.

Therefore, a temperature range of about 140° C. to about 170° C., in an example embodiment, about 140° C. to about 160° C. may be selected to achieve the etching selectivity for the nitride layer greater than about 200 while maintaining the etching rate for the nitride layer in a desired range.

According to example embodiments of the present inventive concepts, an etchant composition for nitride layers may include phosphoric acid and a silicon-fluorine compound. The silicon-fluorine compound may facilitate an etching rate for a nitride layer while suppressing an etching rate for an oxide layer. Thus, a high etching selectivity for the nitride layer relative to the oxide layer greater than, e.g., about 200 may be realized by using the etchant composition. Additionally, the silicon-fluorine compound may have an improved solubility to water or phosphoric acid so that an adsorption of etching residues on a semiconductor substrate or the oxide layer may be prevented.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. An etchant composition for nitride layers, comprising:
phosphoric acid in an amount ranging from about 80 weight percent to about 90 weight percent, based on a total weight of the etchant composition;
a silicon-fluorine compound in an amount ranging from about 0.02 weight percent to about 0.1 weight percent, based on the total weight of the etchant composition, the silicon-fluorine compound including a bond between a silicon atom and a fluorine atom (Si—F bonding); and
a remainder of water.

2. The etchant composition of claim 1, wherein the etchant composition includes the silicon-fluorine compound in an amount ranging from about 0.03 weight percent to about 0.07 weight percent, based on the total weight of the etchant composition.

3. The etchant composition of claim 1, wherein the silicon-fluorine compound includes at least one selected from ammonium hexafluorosilicate, ammonium fluorosilicate, sodium fluorosilicate, silicon tetrafluoride and hexafluorosilicic acid.

4. The etchant composition of claim 1, wherein a silicon compound and a fluorine compound which do not include the Si—F bonding are excluded from the etchant composition.

5. The etchant composition of claim 4, wherein the silicon compound includes oxime silane, silyl sulfate and tetra ethyl ortho silicate (TEOS), and
the fluorine compound includes fluoric acid (HF) and ammonium fluoride.

6. The etchant composition of claim 1, further comprising an etching enhancer.

7. The etchant composition of claim 6, wherein the etching enhancer includes a sulfuric acid-based compound, or an acid ammonium-based compound except for fluoric acid ammonium.

8. The etchant composition of claim 1, wherein an etching selectivity for a nitride layer relative to an oxide layer of the etchant composition exceeds about 200.

9. The etchant composition of claim 8, wherein the etching selectivity for the nitride layer relative to the oxide layer of the etchant composition is in a range from about 250 to about 300.

10. A method of manufacturing a semiconductor device, comprising:
forming insulating interlayers and sacrificial layers alternately and repeatedly on a substrate;
forming a plurality of channels through the insulating interlayers and the sacrificial layers;
partially removing the insulating interlayers and the sacrificial layers to form an opening between adjacent channels of the plurality of channels;
removing the sacrificial layers exposed by the opening using an etchant composition for nitride layers which includes phosphoric acid, a silicon-fluorine compound and a remainder of water, the silicon-fluorine compound including a bond between a silicon atom and a fluorine atom (Si—F bonding); and
forming a gate line in each of spaces from which the sacrificial layers are removed.

11. The method of claim 10, wherein the etchant composition includes phosphoric acid in an amount ranging from about 80 weight percent to about 90 weight percent, the silicon-fluorine compound in an amount ranging from about 0.02 weight percent to about 0.1 weight percent, and the remainder of water, based on a total weight of the etchant composition.

12. The method of claim 11, wherein the etchant composition includes the silicon-fluorine compound in an amount ranging from about 0.03 weight percent to about 0.07 weight percent, based on the total weight of the etchant composition.

13. The method of claim 10, wherein the insulating interlayer includes silicon oxide, and the sacrificial layer includes silicon nitride.

14. The method of claim 13, wherein an etching selectivity for the sacrificial layer relative to the insulating interlayer is in a range from about 200 to about 300.

15. The method of claim 10, wherein the silicon-fluorine compound includes at least one selected from ammonium hexafluorosilicate, ammonium fluorosilicate, sodium fluorosilicate, silicon tetrafluoride and hexafluorosilicic acid.

16. The method of claim 10, wherein removing the sacrificial layers is performed at a temperature in a range from about 140° C. to about 170° C.

17. The method of claim 10, wherein a top surface of the substrate is exposed by the opening.

18. The method of claim 17, further comprising:
forming an impurity region at an upper portion of the substrate exposed through the opening; and
forming a filling layer pattern on the impurity region to fill the opening.

19. The method of claim 10, further comprising forming a dielectric layer structure that surrounds an outer sidewall of the channel.

20. The method of claim 10, wherein silane compound, fluoric acid and ammonium fluoride are excluded from the etchant composition for nitride layers.
